(19) United States
(12) Patent Application Publication
(10) Pub. No.: US 2023/0110544 A1
(43) Pub. Date: Apr. 13, 2023

(54) Wrist-Wearable Heat Diffuser

(71) Applicant: NuCurrent, Inc., Chicago, IL (US)

(72) Inventor: Pratik Halyal, Chicago, IL (US)

(21) Appl. No.: 17/497,351

(22) Filed: Oct. 8, 2021

(51) Int. Cl. H05K 7/20

(52) U.S. Cl. CPC H05K 7/20409; H05K 7/20472

(57) ABSTRACT

A rechargeable wearable electronic device is provided having a device housing with an electronic circuitry module containing a rechargeable power source and a receiver coil for wireless charging of the rechargeable power source as well as a band portion for attaching the wearable electronic device to a user appendage. The band portion includes a heat spreading layer of a thermally conductive material, such that a portion of the heat spreading layer within the device housing is in thermal contact with the electronic circuitry module. An outer skin encapsulates at least a portion of the heat spreading layer. The heat spreading layer is thermally conductive and may contain copper, aluminum, brass or other thermally conductive material.

### TECHNICAL FIELD

The present disclosure generally relates to systems and methods for device cooling, and, more particularly, to a wearable heat diffuser for cooling a wrist-worn device.

### BACKGROUND

Rechargeable portable electronic devices may have charging or operational modes involving high current flow or high switching frequencies. These conditions can result in high heat generation. The high heat may be uncomfortable for the wearer and may also lead to acute or gradual component failure, or intermittent malfunction.

As the demand for wrist wearable devices grows, this problem will become more acute. A wrist wearable device consists of the main body which houses all the electronic parts, and thus is primarily responsible for heat generation, and a silicone band which goes around the wrist to hold the device to the user.

### SUMMARY

As noted above, rechargeable wearable electronic devices can generate a significant amount of thermal energy. In extreme cases, the high heat may become uncomfortable for the wearer and may also lead to device damage or malfunction. As devices become more compact, the close packing of components and associated smaller form factor exacerbate thermal problems. It is possible to partially relieve thermal issues by throttling current usage, thus lowering the amount of waste heat generated. However, implementing this solution means that the desired function, e.g., device charging, will take more time, creating an undesirable impact on users.

To this end, in an aspect of the disclosure, a rechargeable wearable electronic device is provided having a device housing containing an electronic circuitry module containing a rechargeable power source and a receiver coil for wireless charging of the rechargeable power source, as well as a band portion for attaching the rechargeable wearable electronic device to a user appendage. In an aspect, the band portion has a heat spreading layer of a thermally conductive material, such that a portion of the heat spreading layer within the device housing is in thermal contact with the electronic circuitry module.

In a further aspect, an outer skin encapsulates at least a portion of the heat spreading layer. The outer skin may comprise silicone or other suitable material. The heat spreading layer is thermally conductive and may be, for example, a copper band. Other suitably thermally conductive materials may be used additionally or alternatively, e.g., aluminum or brass.

In an aspect, a portion of the heat spreading layer is raised into the device housing relative to nearby portions of the heat spreading layer. In an aspect, the portion of the heat spreading layer within the device housing is in thermal contact with the electronic circuitry module via an intervening layer of a thermally conductive substance.

The heat spreading layer may include a gap opposite the portion of the heat spreading layer within the device housing, and in a further aspect, the gap may be filled with the material of the outer skin, a closure configured to secure the rechargeable wearable electronic device to the user appendage, or may be left open.

In a further aspect, a heat spreading band is provided having a thermally conductive layer with a bare portion configured to contact an electronic circuitry module of the rechargeable wearable electronic device. In this aspect, a covering may substantially enclose the thermally conductive layer except at the bare portion of the thermally conductive layer.

The covering may comprise silicone, and the thermally conductive layer may comprise a metallic or partially metallic band, such as may include copper, aluminum, brass or otherwise. The bare portion of the thermally conductive layer may be raised relative to adjacent portions of the thermally conductive layer and may be, but need not be, coated with a thermally conductive substance.

In an aspect, there is a gap in the thermally conductive layer substantially opposite the bare portion of the thermally conductive layer. If not left open, this gap may be filled by the material of the covering or may contain a closure configured to secure the rechargeable wearable electronic device to the user appendage.

In another aspect of the disclosure, a rechargeable wearable electronic device is provided having a device housing encompassing an electronic circuitry module containing a rechargeable power source and a receiver coil for wireless charging of the rechargeable power source. In this aspect, the device housing may further include a passage for a thermal sink extending through the device housing such that the sink extends beyond the device housing. In an aspect, the passage is configured such that the thermal sink makes thermal contact with the electronic circuitry module.

In yet another aspect of the disclosure, a rechargeable wearable electronic device is provided with an electronic circuitry module containing a rechargeable power source and a receiver coil for wireless charging of the rechargeable power source. A device housing encompassing the electronic circuitry module. The electronic circuitry module may generate heat during wireless charging of the rechargeable power source, and as such, the device housing further including a passage for containing a thermal sink extending through the device housing such that the thermal sink extends beyond the device housing, the passage is configured such that the thermal sink, when installed, makes thermal contact with the electronic circuitry module.

These and other aspects and features of the present disclosure will be better understood when read in conjunction with the accompanying drawings.

### BRIEF DESCRIPTION OF THE DRAWINGS

FIG. 1A is a schematic perspective view of a wearable electronic device in a usage environment.

FIG. 1B is a schematic perspective view of a wearable electronic device in a recharging environment including a recharging power pack.

FIG. 2 is a cross-sectional side view of a wearable electronic device and power pack in accordance with the present disclosure.

FIG. 3 is a simplified exploded perspective view of a wearable electronic device in accordance with the present disclosure.

FIG. 4A is a cross-sectional view of a heat spreading band for a wearable electronic device in accordance with the present disclosure.

FIG. 4B is a cross-sectional view of the heat spreading band of FIG. 4A, with a silicone overlay in accordance with the present disclosure.

FIG. 5 is a simplified partial perspective view of a wearable electronic device, showing the silicone-encased heat spreading band and the relationship thereof with the frame of the wearable electronic device in accordance with the present disclosure.

FIG. 6A is a cross-sectional view of a multi-part heat spreading band for a wearable electronic device in accordance with the present disclosure.

FIG. 6B is a partially exploded top view of the heat spreading band of FIG. 4A, with connection mechanism shown in accordance with the present disclosure.

While the following detailed description will be given with respect to certain illustrative embodiments, it should be understood that the drawings are not necessarily to scale and the disclosed embodiments are sometimes illustrated diagrammatically and in partial views. In addition, in certain instances, details which are not necessary for an understanding of the disclosed subject matter or which render other details too difficult to perceive may have been omitted. It should therefore be understood that this disclosure is not limited to the particular embodiments disclosed and illustrated herein, but rather to a fair reading of the entire disclosure and claims, as well as any equivalents thereto. Additional, different, or fewer components and methods may be included in the systems and methods.

### DETAILED DESCRIPTION

In the following description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

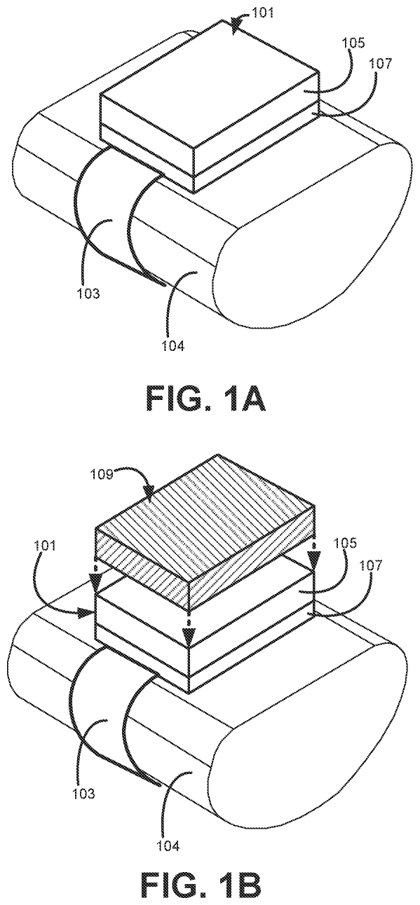

Referring now to the drawings and with specific reference to FIG. 1A, a schematic perspective view of a wearable electronic device in a usage environment is illustrated. The wearable electronic device 101 may be a wrist-worn fitness device or tracking device, for example, and may include sensors, a power system and a communication system. The illustrated wearable electronic device 101 includes a band 103 wrapped around a user appendage 104. The wearable electronic device 101 includes a top portion 105 having a nonferrous outer layer to allow the non-attenuated passage of electromagnetic power and data signals. The top portion 105 of the wearable electronic device 101 is mounted on or affixed to a base portion 107 of the wearable electronic device 101.

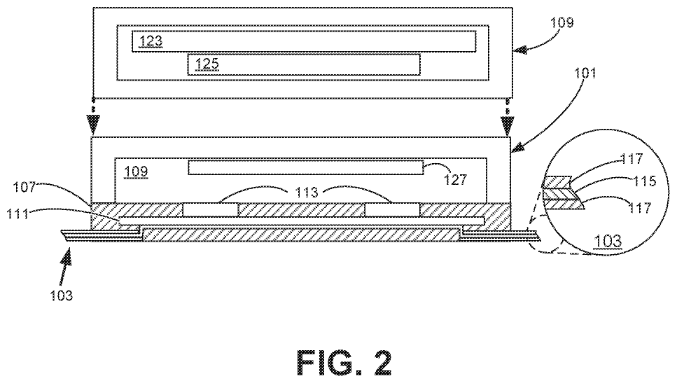

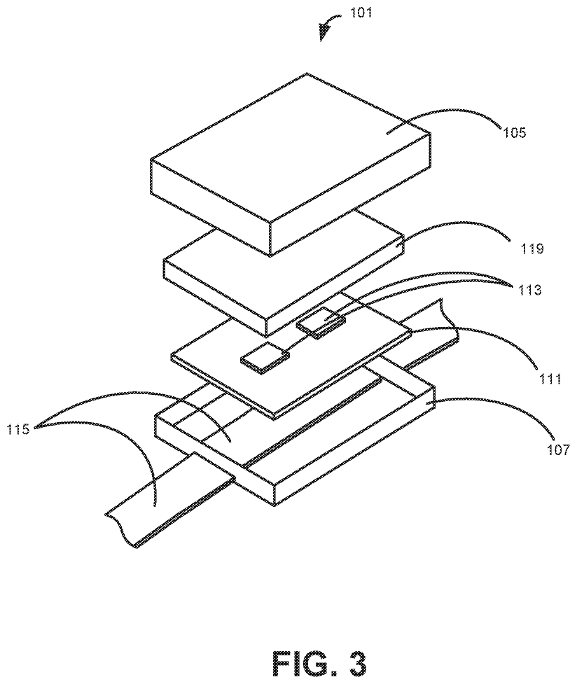

In an embodiment, as shown in FIG. 1B, the wearable electronic device 101 is configured for wireless charging via a power pack 121. The wearable electronic device 101 and power pack 121 includes a number of internal electronic components. The primary internal electronic components are illustrated in greater detail in FIGS. 2 and 3. FIG. 2 is a cross-sectional side view of the wearable electronic device 101 and power pack 121 in accordance with the present disclosure. In the illustrated embodiment, the wearable electronic device 101 further includes an interior space 109 in the top portion 105, within which an electromagnetic power receiver coil 127 is contained. In operation, such as during charging of the device 101, this coil 127 is capable of generating significant heat.

Within the base portion 107, the wearable electronic device 101 includes device circuitry 111 such as may be mounted on a printed circuit board, or otherwise consolidated and connected to function. The device circuitry 111, in an embodiment of the disclosure, includes one or more heat generating components 113 such as regulators, controller, resistors, and so on. The device circuitry 111 may also contain receiver control circuitry for managing the operation of the receiver coil 127.

The power pack 121 as shown in FIG. 1B includes a power source 123 and a transmitter coil 125. Control circuitry (not shown) for managing the operation of the transmitter coil 125 may also be housed with the power pack 121. When the power pack 121 is placed on the wearable electronic device 101, the transmitter coil 125 of the power pack 121 may couple to the receiver coil 127 in the wearable electronic device 101. Once coupled, the transmitter coil 125 transmits, and the receiver coil 127 receives, an electromagnetic power signal during recharging. The power pack 109 may be retained on the wearable electronic device 101 via a strap, magnet, hook and loop material, clip or other suitable retention mechanism.

Although the power transmission protocol employed by the power pack 109 and wearable electronic device 101 need not take any specific form, the operating frequencies employed may comprise relatively high frequency ranges, examples of which may include, but are not limited to, 6.78 MHz (e.g., in accordance with the REZENCE and/or AIRFUEL interface standard and/or any other proprietary interface standard operating at a frequency of 6.78 MHz), 13.56 MHz (e.g., in accordance with the NFC standard, defined by ISO/IEC standard 18092), 27 MHz, and/or an operating frequency of another proprietary operating mode. The operating frequencies employed may be operating frequencies designated by the International Telecommunications Union (ITU) in the Industrial, Scientific, and Medical (ISM) frequency bands, including not limited to 6.78 MHz, 13.56 MHz, and 27 MHz, which are designated for use in wireless power transfer. The transmitter coil 125 and receiver coil 127 of the present disclosure may be configured to transmit and/or receive electrical power having a magnitude that ranges from about 10 milliwatts (mW) to about 500 watts (W).

While the components and their placements within the power pack 109 and wearable electronic device 101 may be designed to minimize heat generation, they may nonetheless inevitably convert some portion of consumed power into waste heat. This waste heat, if not properly managed, can damage not only the heat-generating components themselves, but also other thermally sensitive portions of the device circuitry. In addition to damage, excess heat may cause some portions of the device circuitry 111 to malfunction when hot, causing intermittent thermal problems. This is especially important with respect to the wearable electronic device 101, for which the minimization of bulk is a factor, and thus for which bulky industrial heat sink technology cannot be used.

To this end, referring now to FIG. 3, the band 103 of the wearable electronic device 101 includes a heat spreading layer 115 internal to the band 103 and internal to the wearable electronic device 101. Within the band 103, the heat spreading layer 115 is covered by a silicone or other outer skin 117. However, within the base portion 107 of the wearable electronic device 101, the heat spreading layer 115 is in direct thermal contact with the device circuitry 111, e.g., against the bottom of the PCB holding the heat-generating components 113.

In this way, the heat generated by the heat-generating components 113 is spread to the heat spreading layer 115 beneath the device circuitry 111. From there, the heat continues spreading throughout the entire heat spreading layer 115. Where the heat spreading layer 115 could otherwise contact the wearer's skin, the outer skin 117 of the band 103 prevents contact. The heat energy gradually leaves the band 103 via radiative and conductive cooling, such that the device and band 103 reach thermal equilibrium at a lower temperature than the wearable electronic device 101 alone might achieve.

For greater clarity, FIG. 3 shows a simplified exploded perspective view of the wearable electronic device 101 in accordance with an aspect of the present disclosure. In addition to the aspects illustrated in FIG. 2, FIG. 3 illustrates the battery 119 in an example location within the wearable electronic device 101. The 3D relationship of the heat spreading layer 115 beneath the device circuitry 111 can also be seen in FIG. 3. The heat spreading layer 115 outside of the device is also shown devoid of its outer skin 117 to better illustrate the manner in which the heat spreading layer 115 passes through the base portion 107 of the wearable electronic device 101 and is directly exposed to the device circuitry 111 within the base portion 107. The receiver coil 127 shown in FIG. 2 is omitted here for clarity of the heat exchange path.

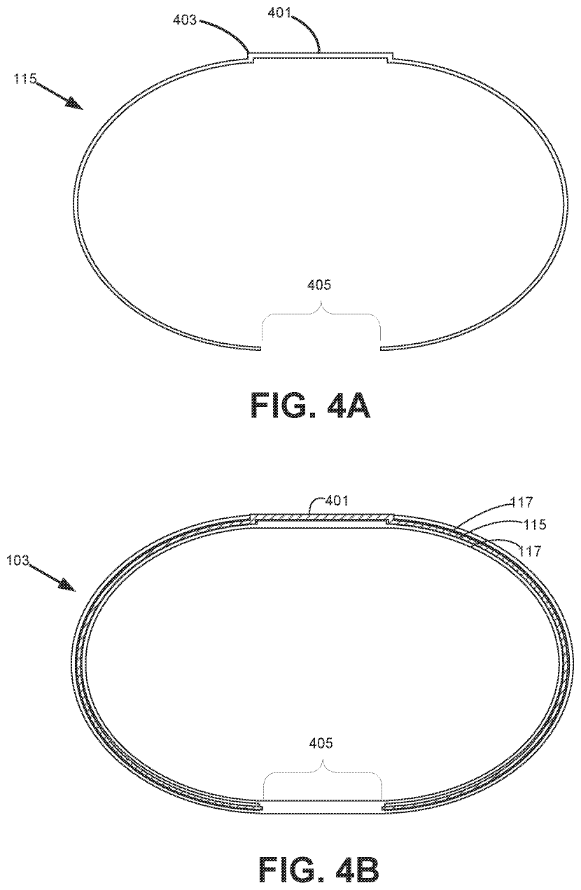

FIGS. 4A and 4B show the heat spreading layer 115 in greater detail in accordance with an aspect of the disclosure. In particular, FIG. 4A is a cross-sectional view of the heat spreading layer 115 in isolation. In the illustrated embodiment, the heat spreading layer 115 includes several features of note. The heat spreading layer 115 is in the form of a band, and includes a raised portion 401 that resides within the device housing, e.g., the base portion 107, in contact with the device circuitry 111 when assembled. The raised portion 401 connects to the remainder of the heat spreading layer 115 via two bends 403. The raising of the raised portion 401 allows the heat spreading layer 115 in that location to be fully within the housing in proximity to the device circuitry 111 without leaving a large gap to the wearer's wrist where the heat spreading layer 115 exits the device housing.

The heat spreading layer 115 also includes a gap 405 opposite the raised portion 401. This gap 405 allows for the expansion of the extent of the heat spreading layer 115 while the wearer dons and removes the wearable electronic device 101. As will be discussed shortly, the manner of application of the wearable electronic device 101 may be elastic or closure-based.

Turning to FIG. 4B, this figure shows a cross-sectional view of the heat spreading band of FIG. 4A, with the silicone overlay skin 117 applied in accordance with the present disclosure to form the band 103. There is no silicone skin above the raised portion 401 of the heat spreading layer 115, to allow direct contact of the heat spreading layer 115 in that region with the device circuitry 111. The gap 405 may be bridged by the silicone overlay skin 117 to allow expansion of the band 103. Alternatively, the gap 405 may include a closure such as a slide, snap, Velcro, buckle or other closure to allow the user to wear and remove the wearable electronic device 101.

The heat spreading layer 115 may be of any thermally conductive material, with the understanding that materials having higher thermal conductivity will provide quicker heat removal. In an aspect of the disclosure, the heat spreading layer 115 is a copper band, but other metallic materials may provide similar, if slightly lesser, cooling. For example, aluminum, brass and other metals and alloys of suitable thermal conductivity can instead be used for the heat spreading layer 115.

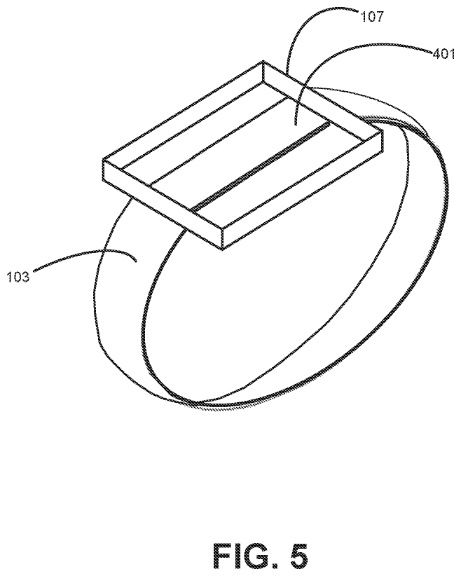

FIG. 5 is a simplified partial perspective view of a wearable electronic device, showing the silicone-encased heat spreading band and the relationship thereof with the frame of the wearable electronic device in accordance with the present disclosure. As can be seen in this view, the raised portion 401 of the heat spreading layer 115 passes and is exposed within the bottom of the base portion 107.

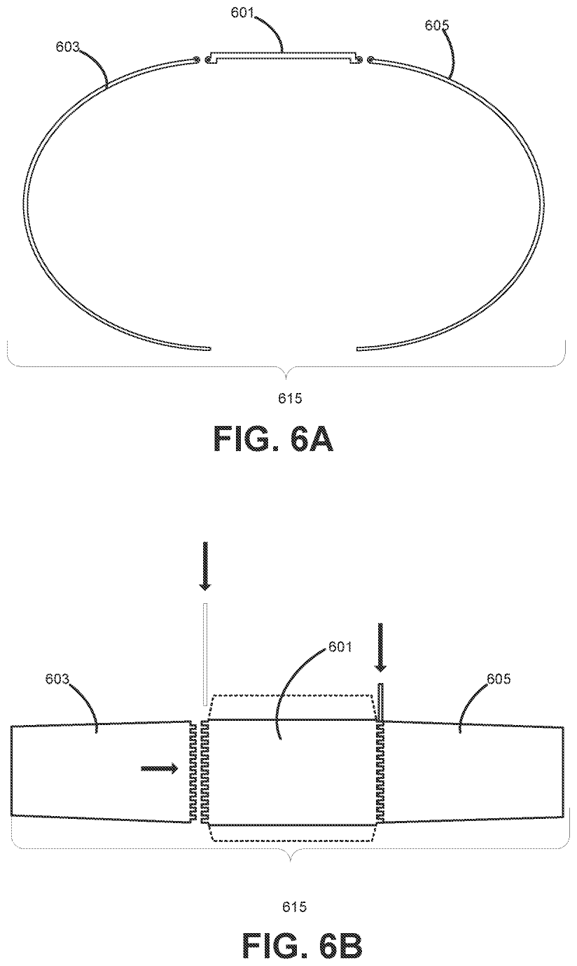

In another embodiment, the continuous heat spreading layer 115 is replaced by a connected multi-part heat spreading layer 615 to allow the user to employ alternative bands on the same wearable electronic device 101. FIGS. 6A and 6B show the heat spreading layer 615 in greater detail in accordance with this aspect of the disclosure. In particular, FIG. 6A is side view of the heat spreading layer 615, while FIG. 6B is a top view of the heat spreading layer 615. In the illustrated embodiment, the heat spreading layer 615 is in the form of a three-part band, and includes a raised central portion 601 that resides within the device housing, e.g., the base portion 107, in contact with the device circuitry 111 when assembled. Two outboard portions 603, 605 of the heat spreading layer 615 are hingedly connected to the central portion 601via high-contact area hinges, such as the pinned highly multi-leafed hinges shown, or via another suitable mechanism. In this way, the outboard portions 603, 605 of the heat spreading layer 615 are attachable to and detachable from the raised central portion 601, but retain a high degree of thermal connectivity.

Thus, by implementing the heat spreading layer(s) 115, 615, proper heat mitigation can be achieved in wearable electronic devices during heat producing functions, such as wireless charging on wrist. Such enhanced heat spreading can provide the ability for greater functionality of the device and/or associated power pack, such as, but not limited to, faster wireless charging and/or faster wireless data throughput. Additionally or alternatively, inclusion of the heat spreading layer may prolong life of electronic components of the wearable device, by reducing thermal-induced stress on electronic components thereof.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The predicate words “configured to”, “operable to”, and “programmed to” do not imply any particular tangible or intangible modification of a subject, but, rather, are intended to be used interchangeably. In one or more embodiments, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as “an aspect” does not imply that such aspect is essential to the subject technology or that such aspect applies to all configurations of the subject technology. A disclosure relating to an aspect may apply to all configurations, or one or more configurations. An aspect may provide one or more examples of the disclosure. A phrase such as an “aspect” may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. An embodiment may provide one or more examples of the disclosure. A phrase such an “embodiment” may refer to one or more embodiments and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples of the disclosure. A phrase such as a “configuration” may refer to one or more configurations and vice versa.

The word “exemplary” is used herein to mean “serving as an example, instance, or illustration.” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the term “comprise” as “comprise” is interpreted when employed as a transitional word in a claim. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

Reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub combination or variation of a sub combination.

What is claimed is:

1. A rechargeable wearable electronic device comprising:
a device portion including a device housing containing an electronic circuitry module, the electronic circuitry module containing a rechargeable power source and a receiver coil for wireless charging of the rechargeable power source, wherein the electronic circuitry module generates heat during wireless charging of the rechargeable power source; and
a band portion for attaching the wearable electronic device to a user appendage, the band portion comprising a heat spreading layer of a thermally conductive material, the heat spreading layer having an inner portion within the device housing that is in thermal contact with the electronic circuitry module, to absorb heat from the electronic circuitry module and spread the absorbed heat to remaining portions of the heat spreading layer.

2. The rechargeable wearable electronic device in accordance with claim 1, further comprising an outer skin encapsulating at least a portion of the heat spreading layer.

3. The rechargeable wearable electronic device in accordance with claim 2, wherein the outer skin comprises a silicone layer.

4. The rechargeable wearable electronic device in accordance with claim 1, wherein the heat spreading layer is a copper band.

5. The rechargeable wearable electronic device in accordance with claim 1, wherein the inner portion of the heat spreading layer is raised into the device housing relative to adjacent portions of the heat spreading layer.

6. The rechargeable wearable electronic device in accordance with claim 1, wherein the inner portion of the heat spreading layer is in thermal contact with the electronic circuitry module via an intervening layer of a thermally conductive substance.

7. The rechargeable wearable electronic device in accordance with claim 1, wherein the heat spreading layer includes a gap positioned substantially opposite the inner portion of the heat spreading layer.

8. The rechargeable wearable electronic device in accordance with claim 7, wherein the gap is filled by a material of an outer skin encapsulating at least a portion of the heat spreading layer.

9. The rechargeable wearable electronic device in accordance with claim 7, wherein the gap contains a closure configured to secure the rechargeable wearable electronic device to the user appendage.

10. The rechargeable wearable electronic device in accordance with claim 1, wherein the heat spreading layer comprises aluminum or brass.

11. A heat spreading band for attaching a rechargeable wearable electronic device to a user appendage, the heat spreading band comprising:
a thermally conductive layer having a bare portion configured to contact an electronic circuitry module of the rechargeable wearable electronic device; and
a covering substantially enclosing the thermally conductive layer except at the bare portion of the thermally conductive layer.

12. The heat spreading band in accordance with claim 11, wherein the covering comprises a silicone layer.

13. The heat spreading band in accordance with claim 11, wherein the thermally conductive layer is a copper band.

14. The heat spreading band in accordance with claim 11, wherein the bare portion of the thermally conductive layer is raised relative to adjacent portions of the thermally conductive layer.

15. The heat spreading band in accordance with claim 11, wherein the bare portion of the thermally conductive layer is coated with a thermally conductive substance.

16. The heat spreading band in accordance with claim 11, wherein the thermally conductive layer includes a gap positioned substantially opposite the bare portion of the thermally conductive layer.

17. The heat spreading band in accordance with claim 16, wherein the gap is filled by a material of the covering.

18. The heat spreading band in accordance with claim 16, wherein the gap contains a closure configured to secure the rechargeable wearable electronic device to the user appendage.

19. The heat spreading band in accordance with claim 11, wherein the thermally conductive layer comprises aluminum or brass.

20. A rechargeable wearable electronic device comprising a device housing encompassing an electronic circuitry module including a rechargeable power source and a receiver coil for wireless charging of the rechargeable power source, wherein the electronic circuitry module generates heat during wireless charging of the rechargeable power source, the device housing further including a passage for containing a thermal sink extending through the device housing such that the thermal sink extends beyond the device housing, the passage being configured such that a thermal sink, when installed in the device housing, makes thermal contact with the electronic circuitry module.
